(19) United States
(12) Patent Application Publication
(10) Pub. No.: US 2017/0338402 A1
(43) Pub. Date: Nov. 23, 2017

(54) NOBLE METAL CAP LAYER FOR A METAL OXIDE CAP OF A MAGNETIC TUNNEL JUNCTION STRUCTURE

(71) Applicants: International Business Machines Corporation, Armonk, NY (US); Samsung Electronics Co., Ltd., Suwon-Si (KR)

(72) Inventors: Guohan Hu, Yorktown Heights, NY (US); Kwangseok Kim, Seoul (KR); Younghyun Kim, Seoul (KR); Jung-Hyuk Lee, Seoul (KR); Jeong-Heon Park, Hwaseong-si (KR)

(21) Appl. No.: 15/157,795

(22) Filed: May 18, 2016

(51) Int. Cl. H01L 43/02; H01L 43/08; H01L 43/10; H01L 43/12

(52) U.S. Cl. CPC H01L 43/02; H01L 43/12; H01L 43/08; H01L 43/10

(57) ABSTRACT

A method for manufacturing a semiconductor device includes forming a magnetic tunnel junction (MTJ) structure comprising a magnetic fixed layer, a non-magnetic barrier layer on the non-magnetic barrier layer and the magnetic free layer on the non-magnetic barrier layer, forming an oxide cap layer on the magnetic free layer, and forming a noble metal cap layer on the oxide cap layer.

### TECHNICAL FIELD

The field generally relates to semiconductor devices and methods of manufacturing same and, in particular, to improving free layer perpendicular magnetic anisotropy (PMA) by capping an oxide cap of a magnetic random access memory (MRAM) device with a noble metal.

### BACKGROUND

Magnetic random access memory (MRAM) (also known as magneto-resistive random access memory) is non-volatile random access memory available as an alternative to dynamic random access memory (DRAM) and static random access memory (SRAM). Data in MRAM is stored by magnetic storage elements formed from ferromagnetic layers having a non-magnetic barrier layer between the ferromagnetic layers in a configuration known as a magnetic tunnel junction (MTJ). A memory device can include a plurality of MTJ structures arranged in, for example, a grid.

A first one of the ferromagnetic layers (also referred to as a “fixed layer”) has a fixed magnetic moment or polarity, and second one of the ferromagnetic layers (also referred to as a “free layer”) has a variable magnetic moment or polarity which is able to be switched between same and opposite directions with respect to the magnetization direction of the fixed layer. Same and opposite magnetic alignment with respect to the fixed layer can be referred to as “parallel” and “antiparallel” states, respectively. When the two ferromagnetic layers are aligned parallel, the resistance is considered to be “low,” and when the two ferromagnetic layers are aligned anti-parallel, the resistance is considered to be “high.” Changing writing current polarities changes the free layer magnetization between parallel and anti-parallel alignment with respect to the fixed layer, which respectively correspond to low resistance “0” and high resistance “1” states. Detecting changes in resistance permits an MRAM device to provide information stored in a magnetic memory element; in other words, perform a read operation.

Spin-transfer torque (STT) refers to an effect in which the orientation of a magnetic layer in an MTJ can be modified using a spin-polarized current. Charge carriers, such as electrons, have an intrinsic spin or angular momentum. An unpolarized electric current includes the same number of electrons having opposite spin from each other, and a spin polarized current includes more electrons of with one spin than an opposite spin. When a current enters the fixed layer, it is polarized by reflection or transmission through the fixed layer. If the spin-polarized current is then directed into the free layer, the angular momentum can be transferred to the free layer, changing its orientation. Using the phenomenon of STT, an STT-MRAM can utilize a lower switching current than conventional MRAM, and delivers the high performance of DRAM and SRAM, at lower power and lower cost.

Magnetic anisotropy refers to the directional dependence of a material's magnetic properties. For example, the magnetic moment of magnetically anisotropic materials will tend to align with an energetically favorable direction of spontaneous magnetization, referred to an “easy axis.” Improving the free layer perpendicular magnetic anisotropy (PMA), and the thermal stability of the free layer is one of the key challenges for STT-MRAM technology.

### SUMMARY

According to an exemplary embodiment of the present invention, a method for manufacturing a semiconductor device includes forming a magnetic tunnel junction (MTJ) structure comprising a magnetic fixed layer, a non-magnetic barrier layer and a magnetic free layer, forming an oxide cap layer on the magnetic free layer, and forming a noble metal cap layer on the oxide cap layer.

According to an exemplary embodiment of the present invention, a semiconductor device includes a magnetic tunnel junction (MTJ) structure comprising a magnetic fixed layer, a non-magnetic barrier layer and a magnetic free layer, an oxide cap layer on the magnetic free layer, and a noble metal cap layer on the oxide cap layer.

According to an exemplary embodiment of the present invention, a method for manufacturing a semiconductor device includes forming a magnetic tunnel junction (MTJ) structure comprising a magnetic fixed layer, a non-magnetic barrier layer on the non-magnetic barrier layer and the magnetic free layer on the non-magnetic barrier layer, forming an oxide cap layer on the magnetic free layer, and forming a noble metal cap layer on the oxide cap layer.

These and other exemplary embodiments of the invention will be described in or become apparent from the following detailed description of exemplary embodiments, which is to be read in connection with the accompanying drawings.

### BRIEF DESCRIPTION OF THE DRAWINGS

Exemplary embodiments of the present invention will be described below in more detail, with reference to the accompanying drawings, of which:

FIG. 1 is a cross-sectional view illustrating a first contact layer formed on a substrate in a method of manufacturing a semiconductor device according to an exemplary embodiment of the present invention.

FIG. 2 is a cross-sectional view illustrating a magnetic fixed layer formed on the first contact layer in a method of manufacturing a semiconductor device according to an exemplary embodiment of the present invention.

FIG. 3 is a cross-sectional view illustrating a non-magnetic barrier layer formed on the fixed layer in a method of manufacturing a semiconductor device according to an exemplary embodiment of the present invention.

FIG. 4 is a cross-sectional view illustrating a magnetic free layer formed on the non-magnetic barrier layer in a method of manufacturing a semiconductor device according to an exemplary embodiment of the present invention.

FIG. 5 is a cross-sectional view illustrating an oxide cap layer formed on the magnetic free layer in a method of manufacturing a semiconductor device according to an exemplary embodiment of the present invention.

FIG. 6 is a cross-sectional view illustrating a noble metal cap layer formed on the oxide cap layer in a method of manufacturing a semiconductor device according to an exemplary embodiment of the present invention.

FIG. 7 is a cross-sectional view illustrating a second contact layer formed on the noble metal cap layer in a method of manufacturing a semiconductor device according to an exemplary embodiment of the present invention.

FIG. 8A is a cross-sectional view illustrating a metal layer formed on the magnetic free layer in a method of manufacturing a semiconductor device according to an exemplary embodiment of the present invention.

FIG. 8B is a cross-sectional view illustrating oxidation of the metal layer from FIG. 8A in a method of manufacturing a semiconductor device according to an exemplary embodiment of the present invention.

FIG. 8C is a cross-sectional view illustrating a metal oxide formed on the oxidized metal layer from FIG. 8B to form a metal oxide cap layer in a method of manufacturing a semiconductor device according to an exemplary embodiment of the present invention.

FIG. 9A illustrates plots of in-plane magnetic hysteresis (M-H) loops showing PMA for oxide capped MTJ stacks without the noble metal cap at various temperatures.

FIG. 9B illustrates plots of in-plane magnetic hysteresis (M-H) loops showing PMA for noble metal and oxide capped MTJ stacks at various temperatures according to an exemplary embodiment of the present invention.

### DETAILED DESCRIPTION

Exemplary embodiments of the invention will now be discussed in further detail with regard to semiconductor devices and methods of manufacturing same and, in particular, to forming a noble metal cap on an oxide cap for an MTJ structure.

It is to be understood that the various layers and/or regions shown in the accompanying drawings are not drawn to scale, and that one or more layers and/or regions of a type commonly used in complementary metal-oxide semiconductor (CMOS), MRAM, STT-MRAM, metal-oxide-semiconductor field-effect transistor (MOSFET), and/or other semiconductor devices in which MTJs may be used, may not be explicitly shown in a given drawing. This does not imply that the layers and/or regions not explicitly shown are omitted from the actual devices. In addition, certain elements may be left out of particular views for the sake of clarity and/or simplicity when explanations are not necessarily focused on the omitted elements. Moreover, the same or similar reference numbers used throughout the drawings are used to denote the same or similar features, elements, or structures, and thus, a detailed explanation of the same or similar features, elements, or structures will not be repeated for each of the drawings.

The semiconductor devices and methods for forming same in accordance with embodiments of the present invention can be employed in applications, hardware, and/or electronic systems. Suitable hardware and systems for implementing embodiments of the invention may include, but are not limited to, personal computers, communication networks, electronic commerce systems, portable communications devices (e.g., cell and smart phones), storage devices, including solid-state media storage devices, functional circuitry, etc. Systems and hardware incorporating the semiconductor devices are contemplated embodiments of the invention. Given the teachings of embodiments of the invention provided herein, one of ordinary skill in the art will be able to contemplate other implementations and applications of embodiments of the invention.

The embodiments of the present invention can be used in connection with semiconductor devices that may require, for example, CMOSs, MRAMs, STT-MRAMs and/or MOSFETs. By way of non-limiting example, the semiconductor devices can include, but are not limited to CMOS, MRAM, STT-MRAM and MOSFET devices, and/or semiconductor devices that use CMOS, MRAM, STT-MRAM and/or MOSFET technology.

As used herein, “height” refers to a vertical size of an element (e.g., a layer, trench, hole, etc.) in the cross-sectional views measured from a bottom surface to a top surface of the element, and/or measured with respect to a surface on which the element is directly on. Conversely, a “depth” refers to a vertical size of an element (e.g., a layer, trench, hole, etc.) in the cross-sectional views measured from a top surface to a bottom surface of the element.

As used herein, “lateral,” “lateral side,” “lateral surface” refers to a side surface of an element (e.g., a layer, opening, etc.), such as a left or right side surface in the cross-sectional views.

As used herein, “width” or “length” refers to a size of an element (e.g., a layer, trench, hole, etc.) in the figures measured from a side surface to an opposite surface of the element.

As used herein, terms such as “upper”, “lower”, “right”, “left”, “vertical”, “horizontal”, “top”, “bottom”, and derivatives thereof shall relate to the disclosed structures and methods, as oriented in the drawing figures. For example, as used herein, “vertical” refers to a direction perpendicular to a substrate in the cross-sectional views, and “horizontal” refers to a direction parallel to a substrate in the cross-sectional views.

As used herein, unless otherwise specified, terms such as “on”, “overlying”, “atop”, “on top”, “positioned on” or “positioned atop” mean that a first element is present on a second element, wherein intervening elements may be present between the first element and the second element. As used herein, unless otherwise specified, the term “directly” used in connection with the terms on”, “overlying”, “atop”, “on top”, “positioned on” or “positioned atop” or the term “direct contact” mean that a first element and a second element are connected without any intervening elements, such as, for example, intermediary conducting, insulating or semiconductor layers, present between the first element and the second element.

Embodiments of the present invention provide a noble metal, such as, for example, iridium (Ir), on a metal oxide cap, which enhances thermal stability and data retention in an MRAM over a wide temperature range. This structure provides improved and controlled oxygen distribution at or near the interface of a metal oxide cap and a magnetic free layer due to the noble metal (e.g., Ir) having low oxidation potential even at high temperatures. The noble metal on the metal oxide cap confines oxygen at or near the interface of the metal oxide cap and the free layer so that ions in the free layer can bond with oxygen in the metal cap across the interface, resulting in strong perpendicular magnetic anisotropy (PMA).

According to an embodiment of the present invention, when compared with conventional structures, a dual cap structure of a noble metal on a metal oxide over a magnetic free layer of an MTJ exhibits significantly higher interface PMA over a wide range of temperatures. In conventional structures, the free layer exhibits instability at certain temperatures, resulting in weak PMA. Embodiments of the present invention significantly improve free layer PMA in perpendicularly magnetized MTJs without sacrificing junction resistance area (RA) and tunnel magnetoresistance (TMR). The addition of a noble metal on a metal oxide cap prevents oxygen diffusion away from the interface of the metal oxide cap and the free layer, which can occur, for example, during an annealing process, thus improving free layer PMA over the wide temperature range.

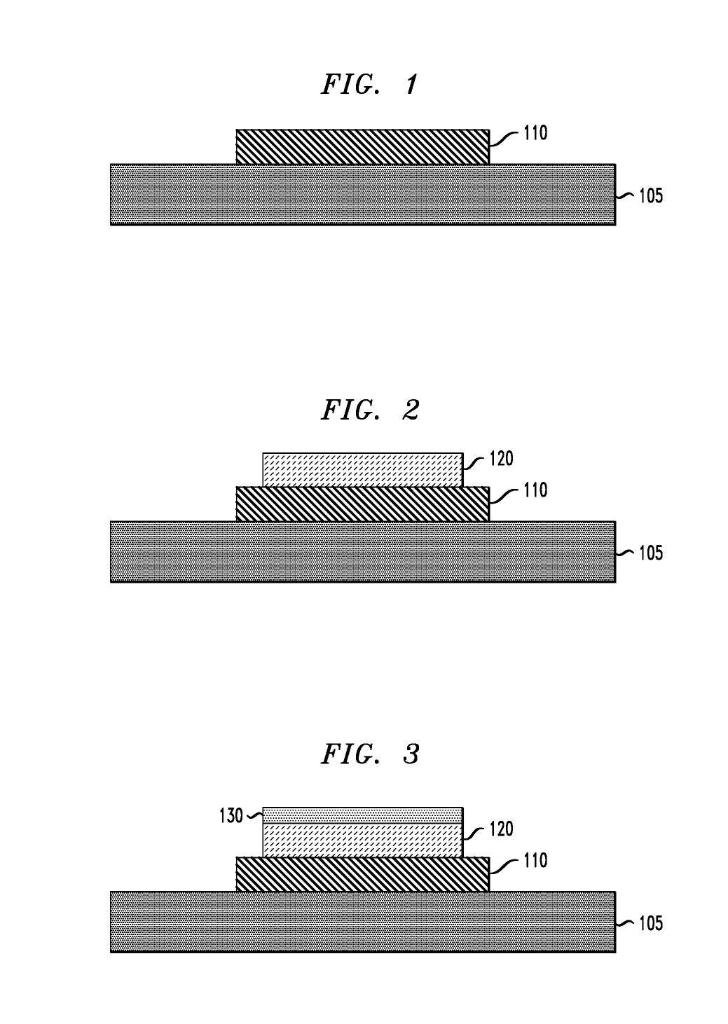

FIG. 1 is a cross-sectional view illustrating a first contact layer formed on a substrate in a method of manufacturing a semiconductor device according to an exemplary embodiment of the present invention. Referring to FIG. 1, a semiconductor substrate 105 may comprise semiconductor material including, but not limited to, Si, SiGe, SiC, SiGeC, II-V compound semiconductor or other like semiconductor. In addition, multiple layers of the semiconductor materials can be used as the semiconductor material of the substrate. Although not shown, according to an embodiment of the present invention, the substrate 105 includes, for example, word lines and transistors, such as, CMOS transistors, which can be used as select devices to drive write currents through respective bits for writing information. For example, in connection with an STT-MRAM, a bottom contact layer 110 (e.g., a bottom electrode) for an MTJ structure comprising fixed, free and barrier layers, is electrically connected to a source/drain of a CMOS transistor on the substrate. Accordingly, although shown on the substrate 105 for purposes of simplicity, the bottom contact layer 110 for an MTJ structure is coupled to a source/drain of a transistor on the substrate through intervening contact layers between the bottom contact layer 110 and the substrate 102. The lower contact layer 110 can be formed using deposition techniques including, but not necessarily limited to, chemical vapor deposition (CVD), plasma enhanced CVD (PECVD), radio-frequency CVD (RFCVD), physical vapor deposition (PVD), atomic layer deposition (ALD), molecular beam deposition (MBD), pulsed laser deposition (PLD), and/or liquid source misted chemical deposition (LSMCD), sputtering, and/or plating. The bottom contact layer 110 includes an electrically conductive material, including, but not necessarily limited to, tantalum, tantalum nitride, copper, titanium, titanium nitride or a combination thereof. The bottom contact layer 110 may have a vertical thickness ranging from about lnm to about 50 nm.

FIG. 2 is a cross-sectional view illustrating a magnetic fixed layer formed on the first contact layer in a method of manufacturing a semiconductor device according to an exemplary embodiment of the present invention. In accordance with an embodiment of the present invention, the magnetic fixed layer 120 can be deposited on the bottom contact layer 110 using deposition techniques including, but not necessarily limited to, CVD, PECVD, RFCVD, PVD, ALD, MBD, PLD, and/or LSMCD, sputtering, and/or plating.

In accordance with an embodiment of the present invention, the magnetic fixed layer 120 can comprise, for example, a seed layer formed on the bottom contact layer 110, wherein the seed layer comprises, but is not necessarily limited to, tantalum (Ta), platinum (Pt), ruthenium (Ru), iridium (Ir), nickel (Ni), chromium (Cr), or alloys thereof, or multilayers having a stacked structure of Y on X, or X on Y, where X═Co, CoFe, CoFeB, Ni, or alloys thereof, and Y=platinum (Pt), iridium (Ir), nickel (Ni), or rhodium (Rh). In accordance with an embodiment of the present invention, the stacked structure of Y on X, or X on Y may repeat 1 to 10 times. A first pinned layer is formed on the seed layer, wherein the first pinned layer comprises, but is not necessarily limited to, PtMn CoFe, CoFeB, NiFe, IrMn, Co, CoNi, Colr, CoPt, or multilayers having a stacked structure of Y on X, or X on Y, where X═Co, CoFe, CoFeB, Ni or alloys thereof, and Y=platinum (Pt), iridium (Ir), nickel (Ni), or rhodium (Rh). In accordance with an embodiment of the present invention, the stacked structure of Y on X, or X on Y may repeat 1 to 10 times. The magnetic fixed layer 120 can further comprise a first nonmagnetic spacer layer including, but not necessarily limited to ruthenium (Ru), rhenium (Re), osmium (Os), iridium (Ir) or alloys thereof formed on the first pinned layer, and a second pinned layer comprising the same or similar materials to that of the first pinned layer, formed on the first spacer layer. The magnetic fixed layer 120 can further comprise a second nonmagnetic spacer layer formed on the second pinned layer and comprising tantalum, tungsten, molybdenum, tantalum-iron alloy or tungsten-iron alloy for increased TMR, and a magnetic layer formed on the second nonmagnetic spacer layer CoFeB, CoFe, Co, Fe, CoB, FeB, multilayers thereof or alloys thereof. The fixed layer 120 may have a vertical thickness ranging from about 1 nm to about 20 nm.

FIG. 3 is a cross-sectional view illustrating a non-magnetic barrier layer formed on the fixed layer in a method of manufacturing a semiconductor device according to an exemplary embodiment of the present invention. A non-magnetic barrier layer 130 is deposited on the fixed layer 120 using deposition techniques including, but not necessarily limited to, CVD, PECVD, RFCVD, PVD, ALD, MBD, PLD, and/or LSMCD, sputtering, and/or plating. The tunnel layer 130 can comprise, for example, one or more oxides including, but not necessarily limited to, elements such as aluminum (Al), lithium (Li), beryllium (Be), sodium (Na), magnesium (Mg), niobium (Nb), titanium (Ti), vanadium (V), tantalum (Ta), and barium (Ba), or one or more nitrides including, but not necessarily limited to, elements such as titanium (Ti) and vanadium (V). The barrier layer 130 may have a vertical thickness ranging from about 0.5 nm to about 3 nm.

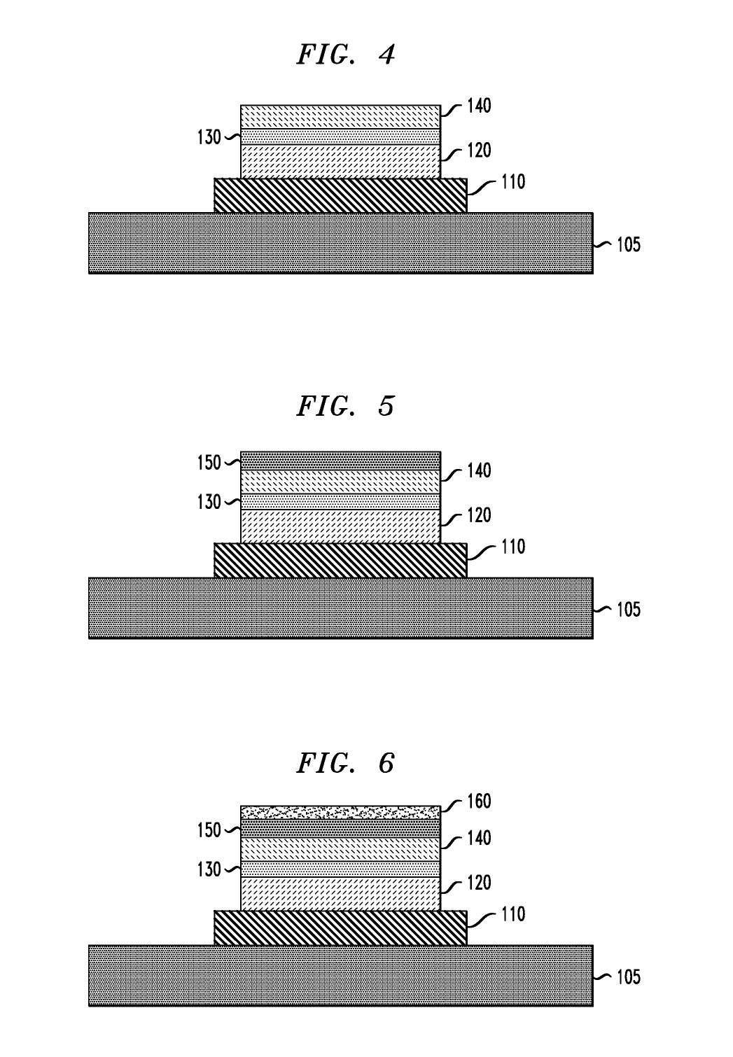

FIG. 4 is a cross-sectional view illustrating a magnetic free layer formed on the non-magnetic barrier layer in a method of manufacturing a semiconductor device according to an exemplary embodiment of the present invention. A free layer 140 is deposited on the barrier layer 130 using deposition techniques including, but not necessarily limited to, CVD, PECVD, RFCVD, PVD, ALD, MBD, PLD, and/or LSMCD, sputtering, and/or plating. The free layer 140 can comprise materials which are the same or similar to those in the fixed layer 120. The free layer 140 may have a vertical thickness ranging from about 0.5 nm to about 5 nm.

It should be noted that the particular makeup of the MTJ structure comprising fixed, free and barrier layers shown in the figures is exemplary only, and that the embodiments of the present invention embodiments may include other MTJ structures having one or more ferromagnetic layers associated with the free and fixed layers thereof.

FIG. 5 is a cross-sectional view illustrating an oxide cap layer formed on the magnetic free layer in a method of manufacturing a semiconductor device according to an exemplary embodiment of the present invention. In accordance with an embodiment of the present invention, the oxide cap layer 150 can be deposited on the free layer 140 using deposition techniques including, but not necessarily limited to, CVD, PECVD, RFCVD, PVD, ALD, MBD, PLD, and/or LSMCD, sputtering, and/or plating. The oxide cap layer 150 can comprise, for example, a metal oxide layer including, but not necessarily limited to, aluminum oxide, lithium oxide, beryllium oxide, sodium oxide, magnesium oxide, niobium oxide, titanium oxide, vanadium oxide, tantalum oxide, tungsten oxide, barium oxide or a combination thereof. The oxide cap layer 150 may have a vertical thickness ranging from about 0.3 nm to about 5 nm. In accordance with an embodiment of the present invention, the oxide cap layer 150 can be deposited using an RF (radio frequency) sputtering process of a metal oxide.

FIG. 6 is a cross-sectional view illustrating a noble metal cap layer formed on the oxide cap layer in a method of manufacturing a semiconductor device according to an exemplary embodiment of the present invention. In accordance with an embodiment of the present invention, the noble metal cap layer 160 can be deposited on the oxide cap layer 150 using deposition techniques including, but not necessarily limited to, CVD, PECVD, RFCVD, PVD, ALD, MBD, PLD, and/or LSMCD, sputtering, and/or plating. For example, according to an embodiment, the noble metal cap layer 160 is deposited using a target comprising the noble metal, and sputtering with argon gas (or other noble gas, such as, for example, xenon, krypton or a combination thereof) at a temperature ranging from, for example, about 178K to about 478K. The target may comprise approximately 100% of the noble metal. The noble metal cap layer 160 can comprise, for example, a noble metal including, but not necessarily limited to, ruthenium, rhodium, palladium, silver, osmium, iridium, platinum, gold or a combination thereof. The noble metal cap layer 160 may have a vertical thickness ranging from about 0.2 nm to about 5 nm.

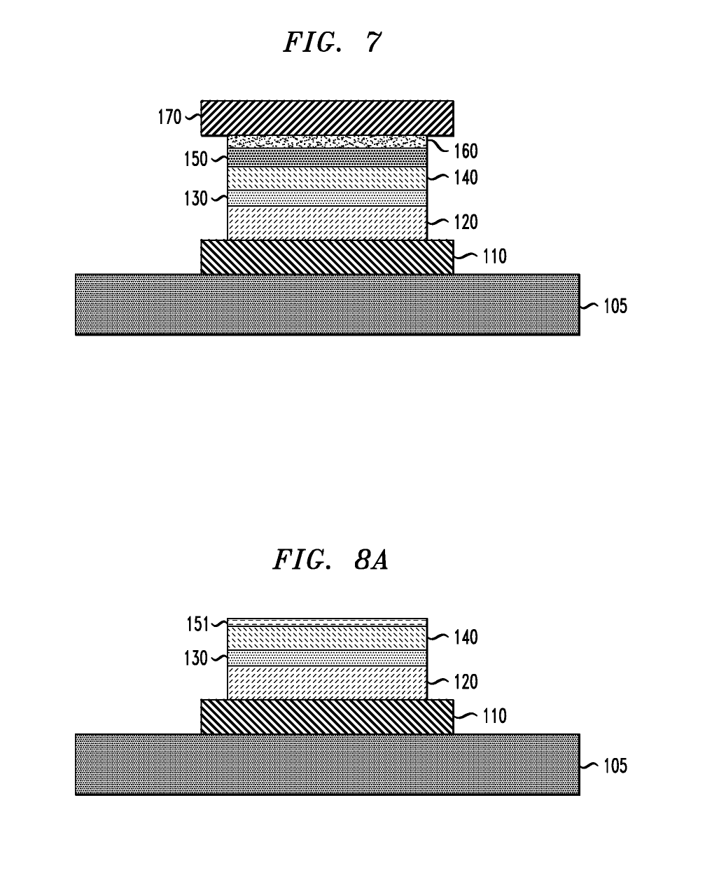

The noble metal cap layer 160 on the metal oxide cap layer 150 confines oxygen at or near the interface of the metal oxide cap layer 150 and the free layer 140, during, for example, a subsequent annealing process, so that ions in the free layer 140 can bond with oxygen in the metal cap layer 150 across the interface, resulting in strong PMA. According to an embodiment, the annealing process is performed after formation of a second contact layer described below in connection with FIG. 7.

FIG. 7 is a cross-sectional view illustrating a second contact layer formed on the noble metal cap layer in a method of manufacturing a semiconductor device according to an exemplary embodiment of the present invention. In accordance with an embodiment of the present invention, a second or upper contact layer 170 (e.g., a top electrode) can be deposited on the noble metal cap layer 160 using deposition techniques including, but not necessarily limited to, CVD, PECVD, RFCVD, PVD, ALD, MBD, PLD, and/or LSMCD, sputtering, and/or plating. Like the bottom contact layer 110, the second or upper contact layer 170 can comprise, for example, an electrically conductive material, including, but not necessarily limited to, tantalum, tantalum nitride, copper, ruthenium, titanium or titanium nitride. The upper contact layer 170 may have a vertical thickness ranging from about 5 nm to about 100 nm. Although not shown, according to an embodiment of the present invention, the upper contact layer 170 can be electrically connected to a bit line.

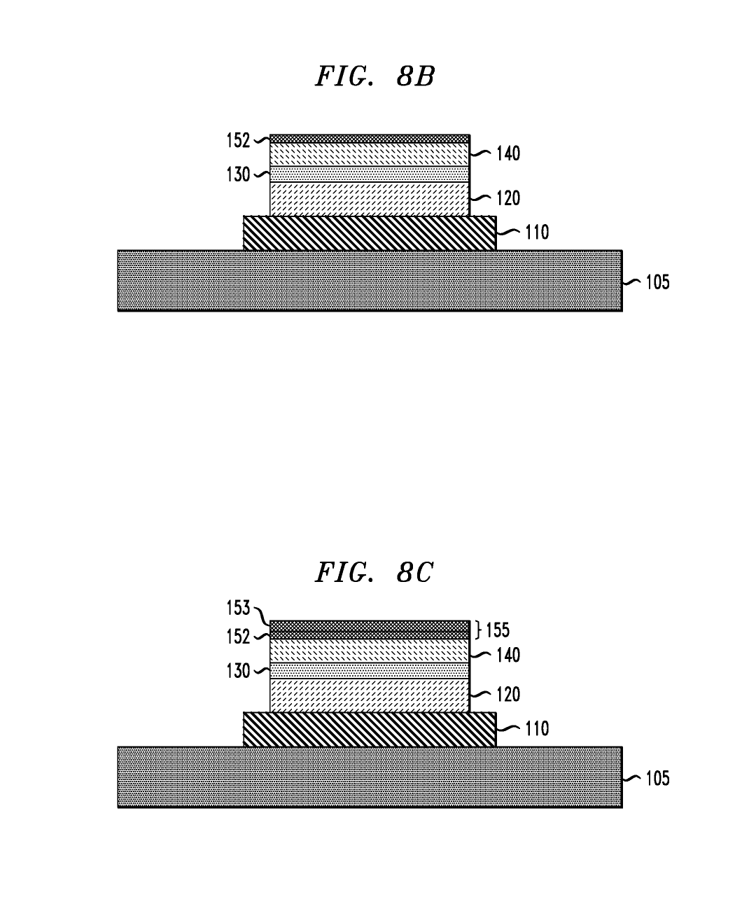

FIGS. 8A-8C illustrate an alternative method for forming an alternate oxide cap layer, which is located between the free layer 140 and the noble metal cap layer 160. Referring to FIG. 8A, which is a cross-sectional view illustrating a metal layer formed on the magnetic free layer in a method of manufacturing a semiconductor device according to an exemplary embodiment of the present invention, a metal layer 151 can be deposited on the free layer 140 using deposition techniques including, but not necessarily limited to, CVD, PECVD, RFCVD, PVD, ALD, MBD, PLD, and/or LSMCD, sputtering, and/or plating. The metal layer 151 can comprise, for example, but is not necessarily limited to, aluminum, lithium, beryllium, sodium, magnesium, niobium, titanium, vanadium, tantalum, tungsten barium or a combination thereof. The metal layer 151 may have a vertical thickness ranging from about 0.1 nm to about lnm. The metal layer 151 should have wettability characteristics with the free layer 140 that cause uniform distribution of the metal layer 151 on the free layer 140.

FIG. 8B is a cross-sectional view illustrating oxidation of the metal layer 151 from FIG. 8A in a method of manufacturing a semiconductor device according to an exemplary embodiment of the present invention. In accordance with an embodiment of the present invention, the metal layer 151 is oxidized using, for example, a mild oxidation process, whereby oxygen is flowed over the metal layer 151 at a temperature which can range from, for example, about 178K to about 478K to oxidize the thin metal layer 151 into a metal oxide layer 152. The oxygen can be flowed in a surfactant layer treatment using, for example, X % oxygen+(100-X %) argon (or other noble gas, such as, for example, xenon, krypton or a combination thereof), where X=about 0.1 to about 100. The flow rate of the oxygen/argon gas can be, for example, about 5 standard cubic centimeter per minute (sccm) to about 500 sccm for about 5 seconds to about 500 seconds. According to an embodiment, the oxidation is performed without using a plasma oxidation process.

FIG. 8C is a cross-sectional view illustrating a metal oxide layer 153 formed on the oxidized metal layer 152 from FIG. 8B to form a metal oxide cap layer 155 in a method of manufacturing a semiconductor device according to an exemplary embodiment of the present invention. In accordance with an embodiment of the present invention, the metal oxide layer 153 can be deposited on the oxidized metal layer 152 using deposition techniques including, but not necessarily limited to, CVD, PECVD, RFCVD, PVD, ALD, MBD, PLD, and/or LSMCD, sputtering, and/or plating. The metal oxide 153 can comprise, for example, a metal oxide layer including, but not necessarily limited to, aluminum oxide, lithium oxide, beryllium oxide, sodium oxide, magnesium oxide, niobium oxide, titanium oxide, vanadium oxide, tantalum oxide, tungsten oxide, barium oxide or a combination thereof. The metal oxide layer 153 may have a vertical thickness ranging from about 0.3 nm to about 5 nm. In accordance with an embodiment of the present invention, the metal oxide 153 can be deposited using an RF (radio frequency) sputtering process of a metal oxide. The combination of the oxidized metal layer 152 and the metal oxide layer 153 forms the metal oxide cap layer 155. The metal oxide cap layer 155 may have a vertical thickness ranging from about 0.2 nm to about 3 nm. In accordance with an embodiment of the present invention, further processing including formation of the noble metal cap layer 160 on the metal oxide cap layer 155 and the second or upper contact layer 170 on the noble metal cap layer 170, as described in connection with FIGS. 6 and 7, can follow the formation of the metal oxide cap layer 155.

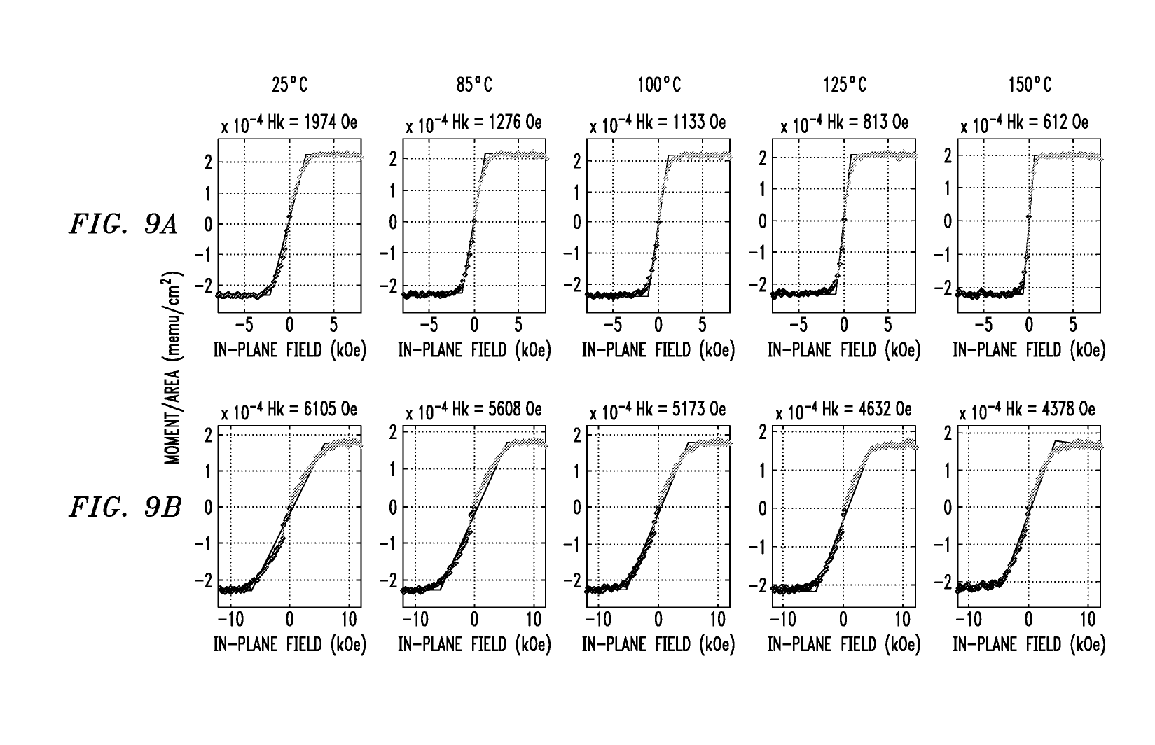

FIG. 9A illustrates plots of in-plane magnetic hysteresis (M-H) loops showing PMA for oxide capped MTJ stacks without the noble metal cap at various temperatures. FIG. 9B illustrates plots of in-plane magnetic hysteresis (M-H) loops showing PMA for noble metal and oxide capped MTJ stacks at various temperatures according to an exemplary embodiment of the present invention. As can be seen, in experiments at temperatures of 25° C., 85° C., 100° C., 125° C. and 150° C., the magnetic field intensity is consistently higher for noble metal and oxide capped MTJ stacks, as opposed to oxide capped MTJ stacks without the noble metal cap. For example, at the temperatures of 25° C., 85° C., 100° C., 125° C. and 150° C., respectively, the magnetic field intensities for noble metal and oxide capped MTJ stacks are 6105, 5608, 5173, 4632 and 4378 Oersteds (Oe) versus 1974, 1276, 1133, 813 and 612 Oe for oxide capped MTJ stacks without the noble metal cap. The addition of the noble metal cap consistently results in increased PMA over a large temperature range. In the plots, the vertical axis (y-axis) corresponds to a measure of perpendicular magnetic anisotropy showing, for example, how much in-plane field should be applied to result in an in-plane perpendicular moment. The horizontal axis (x-axis) of the plots corresponds to in-plane magnetic field intensity.

Although illustrative embodiments of the present invention have been described herein with reference to the accompanying drawings, it is to be understood that the invention is not limited to those precise embodiments, and that various other changes and modifications may be made by one skilled in the art without departing from the scope or spirit of the invention.

1. A method for manufacturing a semiconductor device, comprising:
forming a magnetic tunnel junction (MTJ) structure comprising a magnetic fixed layer, a non-magnetic barrier layer and a magnetic free layer;
forming an oxide cap layer on the magnetic free layer; and
forming a noble metal cap layer on the oxide cap layer;
wherein the noble metal cap layer comprises at least one of rhodium, silver, osmium, iridium, gold and a combination thereof.

2. (canceled)

3. The method according to claim 1, wherein the noble metal cap layer has a vertical thickness ranging from about 0.2 nm to about 5 nm.

4. The method according to claim 1, wherein forming the noble metal cap layer comprises sputtering with a gas at a temperature range of about 178K to about 478K, using a target comprising the noble metal.

5. The method according to claim 4, wherein the target comprises approximately 100% of the noble metal.

6. The method according to claim 4, wherein the gas comprises at least one of xenon, krypton and a combination thereof.

7. The method according to claim 1, further comprising confining oxygen at or near an interface of the oxide cap layer and the magnetic free layer.

8. The method according to claim 7, wherein the confining occurs during an annealing process.

9. The method according to claim 1, wherein forming the oxide cap layer comprises:
depositing a metal layer on the magnetic free layer;
performing an oxidation of the deposited metal layer to form an oxidized metal layer; and
depositing a metal oxide layer on the oxidized metal layer.

10. The method according to claim 1, further comprising forming a contact layer on the noble metal cap layer.

11. The method according to claim 10, wherein the contact layer comprises at least one of tantalum, tantalum nitride, copper, ruthenium, titanium and titanium nitride.

12. A semiconductor device, comprising:
a magnetic tunnel junction (MTJ) structure comprising a magnetic fixed layer, a non-magnetic barrier layer and a magnetic free layer;
an oxide cap layer on the magnetic free layer; and
a noble metal cap layer on the oxide cap layer;
wherein the noble metal cap layer comprises at least one of rhodium, silver, osmium, iridium, gold and a combination thereof.

13. (canceled)

14. The semiconductor device according to claim 12, wherein the noble metal cap layer has a vertical thickness ranging from about 0.2 nm to about 5 nm.

15. A magnetic random access memory (MRAM) comprising the semiconductor device of claim 12.

16. A method for manufacturing a semiconductor device, comprising:
forming a magnetic tunnel junction (MTJ) structure comprising a magnetic fixed layer, a non-magnetic barrier layer on the magnetic fixed layer and a magnetic free layer on the non-magnetic barrier layer;
forming an oxide cap layer on the magnetic free layer; and
forming a noble metal cap layer on the oxide cap layer;
wherein the noble metal cap layer comprises at least one of rhodium, silver, osmium, iridium, gold and a combination thereof.

17. (canceled)

18. The method according to claim 16, wherein the noble metal cap layer has a vertical thickness ranging from about 0.2 nm to about 5 nm.

19. The method according to claim 16, wherein forming the noble metal cap layer comprises sputtering with a gas at a temperature range of about 178K to about 478K, using a target comprising the noble metal.

20. The method according to claim 16, further comprising confining oxygen at or near an interface of the oxide cap layer and the magnetic free layer during an annealing process.
